(19) United States
(12) Patent Application Publication
(10) Pub. No.: US 2023/0110821 A1
(43) Pub. Date: Apr. 13, 2023

(54) ELECTRO-OPTICAL CONVERTER COMPONENT WITH A SPACER, AND A SPACER WAFER FOR PRODUCING AN ELECTRO-OPTICAL CONVERTER COMPONENT

(71) Applicant: SCHOTT AG, Mainz (DE)

(72) Inventors: Ulrich PEUCHERT, Bodenheim (DE); Martin BLEZINGER, Mainz (DE); Simon HERING, Mainz (DE); Fabian WAGNER, Mainz (DE); Markus HEISS-CHOUQUET, Bischofsheim (DE); Vanessa GLÄBER, Mainz (DE); Andreas ORTNER, Gau-Algesheim (DE); Michael DRISCH, Mainz (DE); Annika HÖRBERG, Mainz (DE); Robert HETTLER, Kumhausen (DE); Lars MÜLLER, Wiesbaden (DE)

(73) Assignee: SCHOTT AG, Mainz (DE)

(21) Appl. No.: 18/051,174

(22) Filed: Oct. 31, 2022

Related U.S. Application Data
(63) Continuation of application No. PCT/EP2021/061256, filed on Apr. 29, 2021.

(30) Foreign Application Priority Data
Apr. 29, 2020 (DE) 10 2020 111 728.0

(51) Int. Cl. C03B 33/02; H01S 5/02208; B23K 26/53; B23K 26/0622; B23K 26/352

(52) U.S. Cl. CPC C03B 33/0222; H01S 5/02208; B23K 26/53; B23K 26/0624; B23K 26/3576; B23K 2103/54

(57) ABSTRACT

A spacer wafer for producing spacers of electro-optical converter housings is provided. The spacer wafer is a transparent glass plate having a multiplicity of openings separated from one another and distributed in a grid so that singulated spacers are obtainable by severing sections of the glass plate along separating lines between the openings. The openings have side walls with microstructuring that has a roughness with an average roughness value Rₐ of less than 0.5 μm with a measurement distance of 500 μm.

### CROSS REFERENCE TO RELATED APPLICATIONS

This application is a continuation of International Application PCT/EP2021/061256 filed Apr. 21, 2021, which claims the benefit under 35 USC § 119 of German Application DE 10 2020 111 728.0 filed Apr. 29, 2020, the entire contents of all of which are incorporated herein by reference.

### BACKGROUND

### 1. Field of the Invention

The invention generally relates to optical, in particular electro-optical, systems. In particular, the invention relates to the beam guidance in such electro-optical systems through optical components.

### 2. Description of Related Art

Electro-optical apparatuses typically include a carrier, an electro-optical element in the form of an electro-optical converter arranged on the carrier, and a housing with which the converter is enclosed.

The light that is to be converted, or has been converted, is generally supplied through the housing. The housing is therefore typically transparent at least in certain parts.

### SUMMARY

Electro-optical converters within the meaning of this disclosure can be, in particular, optical imaging apparatuses and/or light sources. This includes light sensors, in particular camera sensors, light-emitting diodes, and laser diodes. Depending on the requirements, complex housings are needed for these electro-optical converters. One important integral part is here customized spacers. These make it possible to set a defined spacing between different active and passive components or contribute to the enclosure and the protection of electromagnetic transducers/emitters/receivers etc., for example for protecting the sensitive components.

Spacers can generally be produced from many materials. The selection is determined by a large number of criteria, including costs, structurability, material properties. Surface properties also come to bear for regions of the spacer in which the connection is established, that is to say the wafer/component surface of most plane-parallel spacers.

Consequently, all materials can be used in principle, including plastics, ceramics, metals, composites. Glass is a preferred choice in respect of cost-effectiveness in connection with chemical resistance etc., among other things.

In the area of laser diodes, in particular VCSELs, structured ceramics are currently used, among other materials. Light is typically emitted here through a housing element placed onto the spacer. The invention is based on the object of expanding the possibilities for coupling light in and out while at the same time enabling a hermetic housing of an electro-optical converter.

Accordingly, in a first aspect, a spacer wafer for producing frame-type spacers for the housing of electro-optical converters by severing sections from the spacer wafer is provided, wherein the spacer wafer comprises a glass plate having a multiplicity of openings which are separated from one another and distributed in a grid, so that the singulated spacers are obtainable by severing sections of the glass plate along separating lines between the openings, wherein the openings have side walls with microstructuring with a roughness, wherein the average roughness value Rₐ is less than 0.5 μm with a measurement distance of 500 μm (±50 μm).

As the case may be, it might not be possible to observe or set a measurement distance of exactly 500 μm. However, the average roughness value Rₐ of less than 0.5 μm is also achieved for a measurement distance that has been shortened by up to 50 μm or in particular lengthened by up to 50 μm. This is why the above indication includes a possible deviation of ±50 μm.

The glass plate is in particular transparent, which means that the light that has been emitted or is to be detected by the electro-optical converter can pass through the microstructured inner wall and thus allows lateral input or output coupling. The invention consequently enables the transmission of light not only through an element that has been placed onto a spacer, but alternatively or additionally also laterally through the spacer.

The spacer can furthermore also act as an optical element and lead to a change in direction or deflection of the light, for example. According to one embodiment, the spacer has, for example, at least one deflecting element, which is integrated in the component. The deflecting element preferably consists here of the same material as the spacer. In particular, the deflecting element is integrated into the spacer such that the spacer and deflecting element form a monolithic component. In particular, the deflecting element is formed by an oblique or curved edge face of the spacer. At the same time, the glass enables an hermetic enclosure.

Using the spacer wafer, an optical system, preferably a camera imaging system, light-emitting diode, or laser diode, in which controlled guiding/output coupling/input coupling/passage of light is made possible, can then be produced.

The openings are preferably produced here using an optical structuring method. Specifically, structuring can be performed by laser-supported ablation or perforation. The inner part surrounded by the closed line of adjacent perforations can be removed by introducing thermal stresses. However, a laser-induced perforation with a subsequent etching process for connecting the holes by removing webs or widening them is particularly preferred. With a laser-based method in particular, free forms can be produced cost-effectively. In addition, these methods in particular are suitable for achieving very small dimensional tolerances of the structure elements with a high level of precision. DE 10 2018 100 299 A1 discloses in principle a combination of laser-based introduction of filament-like defects with a subsequent etching process. In the method described there, the parameters for introducing the filament-like defects and the subsequent etching are set such that the average roughness value of less than 0.5 μm is achieved.

To further reduce costs, the spacers are manufactured on wafer or sheet level. This is advantageous because camera imaging systems and also laser diodes are frequently produced on wafer/sheet level. By using the laser method, in particular with subsequent etching, highly precise positional tolerances hole-to-hole and hole-to-reference point (edge, marker) are realizable, which also enable such wafer-level manufacturing.

The microstructuring of the side wall of the opening has surprisingly proven not to be disadvantageous for the optical properties. To the contrary, the microstructuring can even have advantageous light-shaping properties. For example, for suppressing speckle effects in laser diodes or other interference effects, provision is made in particular for the microstructuring to be irregular and/or for it not to have any structure elements that are arranged strictly in a regular grid. Provision is therefore made according to one embodiment for the microstructuring to have an average roughness value Rₐ of at least 50 nm, preferably at least 100 nm, with a measurement distance of 500 μm.

The invention will be explained in more detail below with reference to the attached figures.

### BRIEF DESCRIPTION OF THE FIGURES

FIGS. 1-2 illustrate exemplary embodiments of spacer wafers;

FIG. 3 illustrates a spacer that has been separated from a spacer wafer;

FIGS. 4-7 illustrate different embodiments of separated spacers with different edge faces;

FIG. 8 shows a laser processing apparatus;

FIG. 9 shows a glass plate that has been processed with a laser;

FIGS. 10a-10c shows color-coded two-dimensional height profiles of a microstructure on the inner wall of an opening;

FIG. 11 shows measured values of the average roughness value as a function of the number of laser pulses for different spacings between the points of incidence of the laser pulses; and

FIG. 12 shows an electro-optical converter component with a spacer.

### DETAILED DESCRIPTION

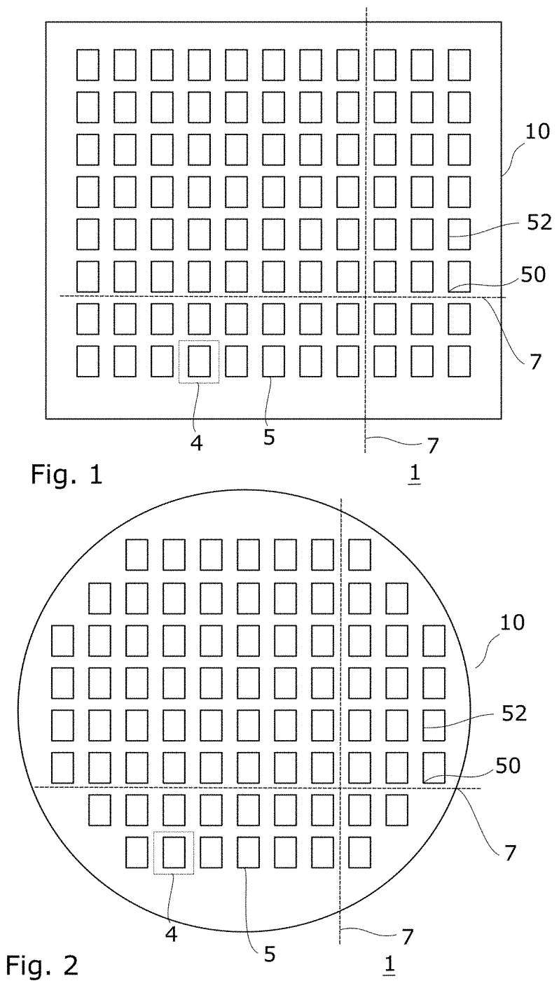

FIGS. 1 and 2 show two examples of spacer wafers 1 from above. The two exemplary embodiments essentially differ in their outer shapes. The embodiment of FIG. 1 provides a rectangular or square spacer wafer 1, while the embodiment of FIG. 2 provides a round spacer wafer 1. A round shape of the spacer wafer 1, as is shown by the example in FIG. 2, can be beneficial for example for a wafer-level packaging process in which the spacer wafer 1 is connected to a functional wafer before being separated.

The spacer wafer 1 serves for producing spacers 2 for the housing of electro-optical converters by severing sections 4 from the spacer wafer 1. The spacer wafer 1 comprises or consists of a transparent glass plate 10. The latter has a multiplicity of openings 5, which are separated from one another and distributed in a grid. If sections 4 of the glass plate 10 are severed along separating lines 7 running between the openings 5, singulated spacers 2 are obtained which each have an opening 5 with a perimetric, closed periphery. The openings 5 have side walls 50 with microstructuring with a roughness. This roughness has an average roughness value Rₐ of less than 0.5 μm with a measurement distance of 500 μm.

Without restriction to the illustrated examples, it is an advantage for the production of spacers for optical systems that the transparent glass plate 10 has a thickness in the range from 100 μm to 3.5 mm, preferably in the range from 200 μm to 3.0 mm.

According to another embodiment, the glass plate has a very low thickness variation (TTV=total thickness variation). The thickness variation of the transparent glass plate in this embodiment is less than 10 μm, preferably 5 μm, preferably less than 2 μm, with particular preference less than 1 μm. This low TTV value is beneficial, among other things, for being able to connect the various wafers over their whole surfaces to one another when assembling the housed electro-optical converters on wafer level. A low TTV value is also beneficial for being able to very precisely position an optical component which has been applied on the spacer or is connected to the spacer. To ascertain the thickness variation, thickness measurement values are ascertained distributed over the wafer, and the difference between the greatest thickness measurement value in absolute terms and the smallest thickness measurement value in absolute terms is then formed as the TTV. A low TTV is likewise important to achieve the most uniform spacing possible, in particular in optical systems. If these fluctuate on the wafer level, the spacers made therefrom have varying thicknesses, and each individual camera module must be controlled or compensated with respect to the path length between the lens or filter elements.

In addition to the TTV, a thickness tolerance, i.e., uniformity of thickness from wafer to wafer, is also required. This should lie, for example, below 10 μm, preferably be <=5 μm.

According to a particularly preferred embodiment, which is also realized in the two exemplary embodiments of FIG. 1 and FIG. 2, the side walls 50 of the openings 5 each have at least one planar section 52. The light can pass through said planar section without the side wall 50 acting as a lens or a cylindrical lens or deforming the spatial intensity profile of the light in any way.

Generally, and without limitation to the specific examples illustrated, the side walls 50 of the openings 5 can have four planar sections 52. In particular, two planar sections 52 can in each case lie opposite each other. This feature has been satisfied in particular if the openings 5 have a rectangular or square basic shape. However, the feature has also been satisfied if the corners of rectangular or square openings 5 are rounded.

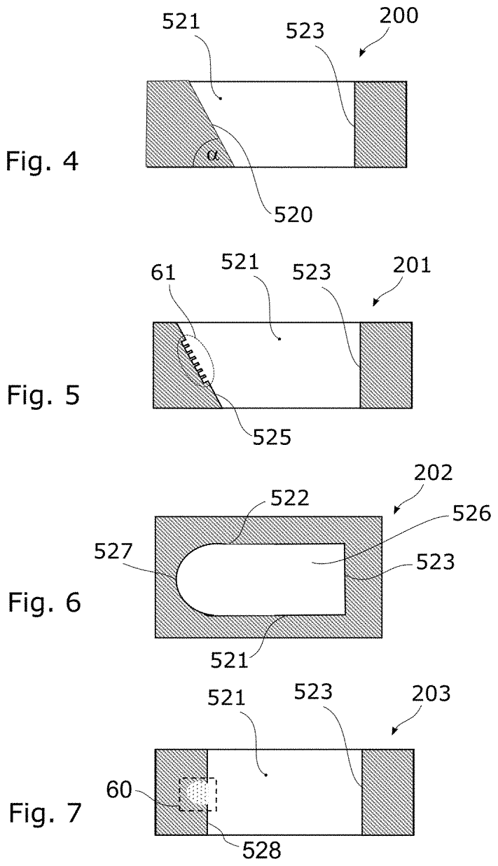

Alternatively, the side walls 50 of the openings 5 can also have at least one non-planar section 520. This is illustrated in FIG. 4. The section in question, or the edge face 520, can here have in particular an oblique, curved, or helical shape. An oblique section or an oblique edge face 520 can represent, for example, a deflection element, and a light beam can thus be coupled in or out vertically in a targeted manner. By using corresponding spacers, the light can thus be coupled out vertically even when a horizontally edge-emitting light source is used, without further optical elements, such as mirrors, being required for this purpose in addition to the spacer.

Alternatively or additionally, further components, for example beam-controlling elements, can be placed on the oblique sections. In this case, the use of a corresponding spacer with an oblique section ensures angle-preserving positioning of the additional components, without a great deal of mounting outlay being required for this purpose. Furthermore, a corresponding component can also be obtained by coating the oblique edge face, for example to produce a highly reflective surface. The oblique edge face can here be coated completely or only partially. Preferably, the oblique edge face has a coating in the partial regions in which the light is incident.

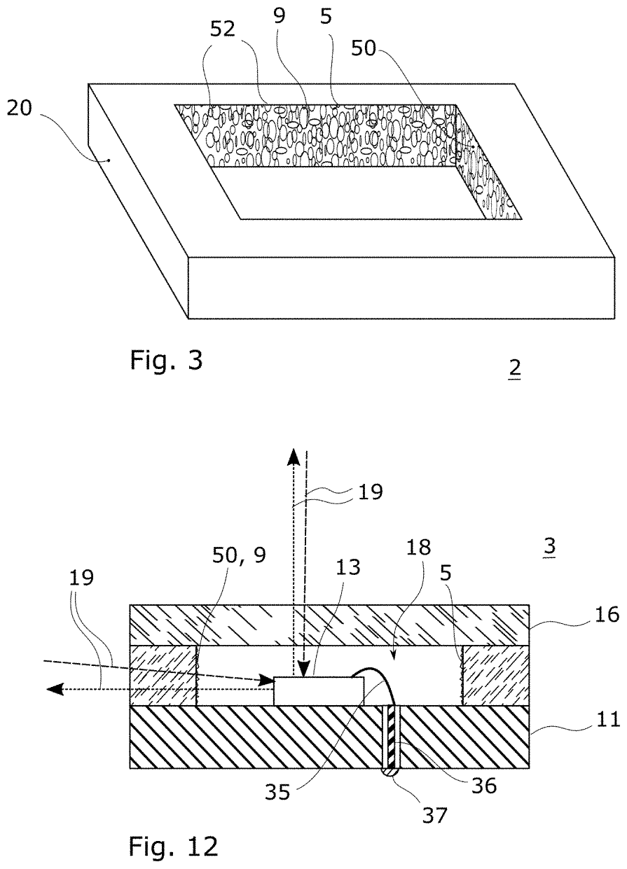

A singulated spacer 2 obtained by severing a section is shown in a perspective view in FIG. 3. The spacer 2 is producible by severing a section 4 from a spacer wafer 1, wherein the spacer 2 constitutes a frame-type element having an opening 5 whose side wall 50 is provided with microstructuring 9, wherein the microstructuring 9 has a roughness having an average roughness value Rₐ of less than 0.5 μm with a measurement distance of 500 μm. The in particular irregular microstructuring 9 is symbolized in FIG. 3 by irregularly arranged circles and ellipses of different sizes.

The outer wall 20 of the spacer 2 can likewise have such microstructuring 9. However, other surface structures, even a polished surface, are also possible, depending on the severing method and any optional postprocessing. In particular, consideration is given to the fact that assembly of the electro-optical converter components is carried out on the wafer bond. Next, the outer wall is formed preferably when separating the wafer bond of the spacer wafer 1 with a functional wafer or the wafers carrying converter elements. Accordingly, a functional or carrier wafer connected to the spacer wafer 1 is then at the same time also separated along the separating lines shown in FIG. 1 and FIG. 2. Generally, glasses with coefficients of expansion of less than 8·10⁻⁶ K⁻¹ are preferred for the spacer wafer 1 in order to keep thermomechanical stresses in particular in the wafer bond with the materials that are customary therefor low.

With the selection of the glass used, it is additionally possible to adapt the coefficient of thermal expansion of the spacer to the coefficients of thermal expansion of further components mounted together with the spacer.

The production of the spacer wafer 1 according to a particularly preferred embodiment of the production method will be described below.

In the method for producing a spacer wafer 1 or a spacer 2, the laser beam 27 of an ultrashort pulse laser 30 is aimed at one of the side faces 102, 103 of a transparent glass plate 10 and is concentrated using a focusing optical unit 23 to an elongate focus in the transparent glass plate 10 (without limiting the ratios of glass plate thickness to focal length, i.e., the focus can lie entirely in the substrate or can intersect one or both substrate surfaces), wherein the incoming energy of the laser beam 27 produces a filament-type defect 32 in the volume of the transparent glass plate 10, whose longitudinal direction runs transversely to the side face 102, 103, in particular perpendicular to the side face 102, 103, and the ultrashort pulse laser 30 sends a pulse or a pulse packet with at least two successive laser pulses to produce a filament-type defect, and wherein the point of incidence 73 of the laser beam 27 on the transparent glass plate 1 is guided along a specified closed path and consequently a multiplicity of filament-type defects 32 located next to one another on the path are introduced, wherein after the filament-type defects 32 have been introduced, the transparent glass plate 10 is exposed to an etching medium 33, and in this way the filament-type defects 32 are widened to form channels, wherein the diameter of the channels is enlarged by the etching until the glass between the channels has been removed and the channels combine and form an opening 5, wherein the etching produces microstructuring 9 having a roughness whose average roughness value Rₐ is less than 0.5 μm with a minimum distance of 500 μm.

The shape of the closed path, along which the point of incidence of the laser beam is guided, consequently determines the contour of the opening.

According to one refinement, at least partial regions of the spacer wafer 1 or of the spacer 2 are subsequently polished or ablated. This can be accomplished in particular using a pulsed laser, for example an ultrashort pulse laser. The pulse duration of the laser is preferably at most 10 ps, preferably at most 4 ps, and with particular preference at most 1 ps. The use of a CO₂ laser has in particular proven to be advantageous for laser polishing.

According to one embodiment, partial regions of the spacer wafer 1 or of the spacer 2 are ablated, after the etching process, by the treatment with an ultrashort pulse laser. For example additional structures that act as optical elements can be produced by the ablation of material in the corresponding regions. It is thus possible for example to obtain microlenses or diffuser elements within the spacer wafers 1 or the spacer 2. Alternatively or additionally, partial regions of the spacer wafer 1 or of the spacer 2 can also be beveled by laser ablation. According to a preferred embodiment, at least the ablated partial regions of the spacer wafer 1 or of the spacer 2 are subsequently subjected to laser polishing. However, the laser polishing can also take place independently of any preceding laser ablation. According to one embodiment of the production method according to the invention, for example, laser polishing of at least one partial region of the spacer wafer 1 or of the spacer 2 takes place after the etching operation.

The spacer wafer 1 or the spacer 2 preferably has at least one partial region whose average roughness value Rₐ is less than 0.05 μm or even at most 0.04 μm over a measuring distance of 500 μm (±50 μm). According to another embodiment, the average roughness value Rₐ in at least one partial region is less than 20 nm, preferably less than 10 nm with a measuring distance of 50 μm.

According to one embodiment, the spacer wafer 1 or the spacer 2 has an average arithmetic height Sₐ at least in a partial region of less than 5 nm, less than 2 nm, or even at most 1 nm. Preferably, the average arithmetic height Sₐ is determined over a surface area of 500 μm². The average arithmetic height Sₐ is the extension of the line roughness parameter Rₐ to the surface. The parameter Sₐ describes the mean value as an absolute value of the difference in height of each point compared to the arithmetic mean of the surface.

Laser polishing can here increase the optical quality of the corresponding partial region.

According to another embodiment, spacers 2 or partial regions of the spacer 2 that have not been subject to any laser ablation also have a laser-polished surface. For one, the surface roughness can be reduced further hereby.

According to one embodiment, the side walls of the spacer wafer 1 or of the spacer 2 have at least two regions with different average roughness values Rₐ₁ and Rₐ₂. The average roughness value Rₐ₁ in this case is lower than the average roughness value Rₐ₂. Preferably, the side wall in the partial region having the average roughness value Rₐ₁ has no microstructure or has at least one microstructure that is less pronounced (compared to the microstructure in partial regions having an average roughness value Rₐ₂). Preferably, the difference between the average roughness values ΔRₐ=Rₐ₂−Rₐ₁ is at least 10 nm, preferably at least 60 nm, and with particular preference at least 80 nm. The smaller average roughness value Rₐ₁ can in particular be achieved by laser polishing the corresponding partial region of the spacer wafer 1 or of the spacer 2. Laser polishing here leads to a reduction in the microstructuring of the corresponding partial region of the spacer wafer 1 or of the spacer 2. According to one embodiment, at least the region of the spacer wafer 1 or of the spacer 2 on which the light beam is incident when the spacer 2 is used in a component is subjected to laser polishing. The partial regions of the component on which the light beam is incident during operation thus has, according to one embodiment, an average roughness value Rₐ of less than 50 nm, preferably of at most 40 nm. According to one configuration, the average roughness value Rₐ in the relevant partial regions of the component is even less than 40 nm.

FIG. 4 shows a schematic side view of a cross section through a further exemplary embodiment of a spacer 200 which has already been singulated. The spacer 200 has, in addition to three side walls with planar edge faces (521, 523, missing side wall not illustrated), a side wall having an oblique edge face 520. The edge face 520 is here at an angle α to the bottom surface (not illustrated) of the spacer 200. According to one refinement of the production method according to the invention, the angle α can here be set as desired. For example, the edge face 520 can have an angle α of 45°. The high degree of flexibility regarding the angle α is enabled here both by the material of the spacer used and by the method for the production thereof. Thus by using glass as the material for the spacer, the etching angle is limited not by a specified crystal structure, as is the case, for example, when etching silicon crystals. Furthermore, the angle α can also be set by inclining the laser during filamentation. Alternatively or additionally, individual regions can also be beveled by way of a laser ablation process after the etching operation.

According to one refinement, individual partial regions of the spacer wafer 1 or of the spacer 2, for example only one of the edge faces, are processed by laser ablation. This enables the individual edge faces of the spacer 200 to be designed in different ways.

FIG. 5 schematically illustrates a side view of a cross-section through a further exemplary embodiment of a spacer 201 with an oblique edge face 525, wherein material was removed by laser ablation in the partial region 61 of the edge face 525. Owing to its surface structure, the partial region 61 can function as an optical element.

FIG. 6 shows a top view of a schematic illustration of an exemplary embodiment. The spacer 202 illustrated here has the edge faces 521, 522, 523 and 527. The edge face 527 is here concavely curved. The curvature of the edge face 527 was produced in the exemplary embodiment 202 shown in FIG. 6 by removing material by means of laser ablation. In addition, the surface of the edge face 527 is laser-polished. The edge face 527 can here have, in addition to the bottom surface of the spacer 526, an angle α□≠90°, i.e., the edge face 527 can be an oblique edge.

The exemplary embodiments 200, 201, 202 schematically illustrated in FIGS. 4 to 6 have edge faces 520, 524 and 527, which have a different geometry than the other three edge faces. The geometry of the individual edge faces of the spacer can be set freely due to the high degree of flexibility of the production method. Thus, embodiments in which the spacer has a plurality of edge faces at an angle of a 90° are also possible, wherein the angles α of the individual edge faces can differ from one another. It is also possible to produce individual edge faces with different geometries or structures. Consequently, spacers with more complex structures or geometries are also attainable in only a few process steps. According to a preferred embodiment, the spacer has three perpendicular edge faces, that is to say having an angle α=90°, and an oblique or curved edge face having an angle α≠90°. According to one embodiment, the spacer has at least one edge face having an angle α<56°.

According to one refinement, the spacer has at least one oblique edge face having an angle α≠90°, wherein the edge face has a planar surface, and a beam-steering element, for example in the form of a mirror, is mounted on the edge face. According to another embodiment, a round spacer having a continuous inner edge face is provided, wherein the angle α of the edge face or of the hole's inner wall continuously changes toward the bottom of the component within the spacer. The spacer thus has a region for the angle α, with the angle α being location-dependent. If the inner edge face of the spacer in a component functions as a region of incidence for a light beam, the output coupling angle can be set by rotating the spacer.

Furthermore, deliberate structures can also be introduced into at least one of the edge faces. This is illustrated by a further exemplary embodiment in FIG. 7. In this exemplary embodiment, the edge face 528 locally has a curved structure 60. The structure 60 can be produced in particular after the etching operation by ablation of the corresponding partial region with an ultrashort pulse laser and subsequent laser polishing of the corresponding partial region of the edge face 528. The structure 60 can here be configured such that it forms an optical element within the spacer. It is thus possible for example by means of laser ablation to integrate concave mirrors, beam-scattering elements, microlenses, or user-configured free forms into the spacer.

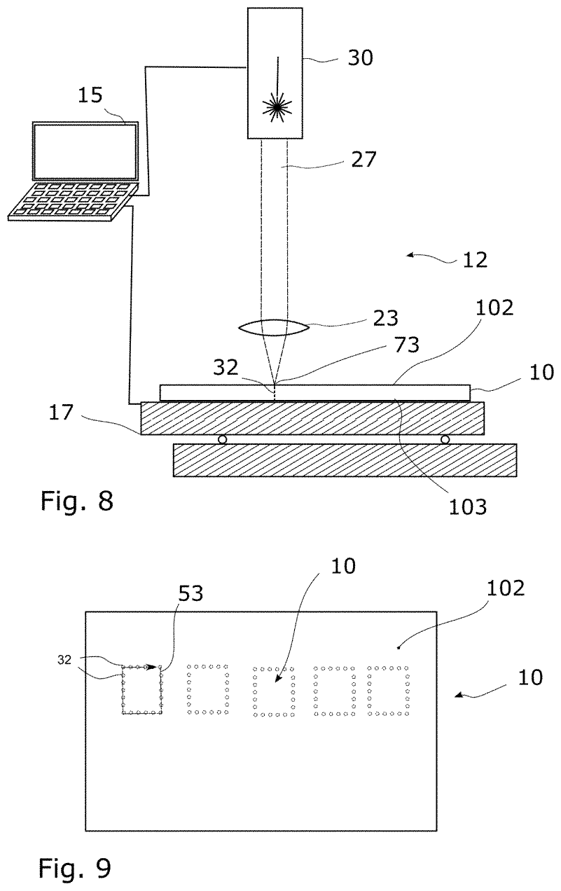

FIG. 8 shows an exemplary embodiment for a laser processing apparatus 12 with which filament-type defects 32 can be introduced into a transparent glass plate 10 in order to subsequently introduce channels at the points of the filament-type defects 32 in an etching process. The apparatus 12 comprises an ultrashort pulse laser 30 having a focusing optical unit 23, connected upstream, and a positioning device 17. Using the positioning device 17, the point of incidence 73 of the laser beam 27 of the ultrashort pulse laser 30 can be positioned laterally on the side face 102 of a transparent glass plate 10 to be processed. In the example shown, the positioning device 17 comprises an x-y stage, on which the transparent glass plate 10 is placed on a side face 103. Alternatively or additionally, it is also possible to design the optical unit to be movable so as to move the laser beam 27 in a manner such that the point of incidence 32 of the laser beam 27 is movable while the transparent glass plate 10 is fixed.

The focusing optical unit 23 now focuses the laser beam 27 into a focus that is elongate in the beam direction, that is to say correspondingly transverse, in particular perpendicular to the irradiated side face 102. Such a focus can be produced for example with a conical lens (what is known as an axicon) or with a lens having a great spherical aberration. The positioning device 17 and the ultrashort pulse laser 30 are preferably controlled by means of a program-technologically set-up computation device 15. In this way, predetermined patterns of filament-type defects 32 distributed laterally along the side face 2 can be produced, in particular by reading position data, preferably from a file or via a network. In order to produce an opening 5, the position data produce a closed, or annular, path.

According to one exemplary embodiment, the following parameters can be used for the laser beam:

The wavelength of the laser beam is 1064 nm, which is typical for a YAG laser. A laser beam having a raw beam diameter of 12 mm is produced, which is then focused with an optical unit in the form of a biconvex lens having a focal length of 16 mm. The pulse duration of the ultrashort pulse laser is less than 20 ps, preferably approximately 10 ps. The pulses are emitted in bursts of 2 or more, preferably 4 or more pulses. The burst frequency is 12-48 ns, preferably approximately 20 ns, the pulse energy is at least 200 microjoules, the burst energy is accordingly at least 400 microjoules.

Subsequently, after one or in particular a multiplicity of filament-type defects 32 have been introduced, the transparent glass plate 10 is removed and placed in an etching bath, where, in a slow etching process, glass is removed along the filament-type defects 32, and so a channel is introduced into the transparent glass plate 10 in each case at the point of such a defect 32.

In one embodiment, an alkaline etching bath having a pH>12, for example a KOH solution with >4 mol/l, preferably >5 mol/l, with particular preference >6 mol/l, but <30 mol/l is used. According to one embodiment of the invention, etching is performed independently of the etching medium used at a temperature of the etching bath of >70° C., preferably >80° C., with particular preference >90° C.

FIG. 9 shows, in a plan view of a side face 2, a glass element 1 having a multiplicity of filament-type defects 32, which are arranged in a specific pattern, as can be written into the glass element 1 by way of the above-described computer-controlled control of the positioning device 17 and the ultrashort pulse laser 30. Specifically, the filament-type defects 32 have been introduced here into the transparent glass plate by way of example along specified closed paths 53 in the form of closed rectangular lines. One of the paths 53 is shown as a dashed line. It is evident to a person skilled in the art that the method can be used not only to trace rectangular paths 53, but paths 53 having any shape.

If channels form and combine at the filament-type defects during the subsequent etching, the inner part 54 defined by the closed path 53 will come out and leave behind an opening 5.

Generally, microstructuring 9 which is characterized by a multiplicity of dome-shaped depressions can be obtained by selecting a suitable etching process. In particular, these depressions can be separated by comparatively sharp ridges. Since the ridges at which convex radii of curvature occur are only narrow, the microstructuring according to one embodiment can also be characterized such that the ratio of the area proportion having a convexly curved surface to the area proportion having a concavely curved surface (as is present for example in the dome-shaped depressions) is at most 0.25, preferably at most 0.1.

This microstructuring has proven to be particularly expedient for only slightly influencing the light passing through.

The size, shape, and depth of the depressions and consequently also the value of the average roughness value can further be influenced by the etching process and the parameters of the laser processing.

Low etching rates are preferred. According to a refinement of the method, the glass of the transparent glass plate 10 is removed with a removal rate of less than 5 μm per hour. In particular, the desired average roughness values can also be achieved by means of the total etching duration. It is expedient for this purpose if the etching duration is at least 12 hours. Preferably, the distance (“pitch”) between the filament-type defects is adapted to the etching duration and the etching rate, and so superfluous etching if the inner part 54 has already come out is avoided.

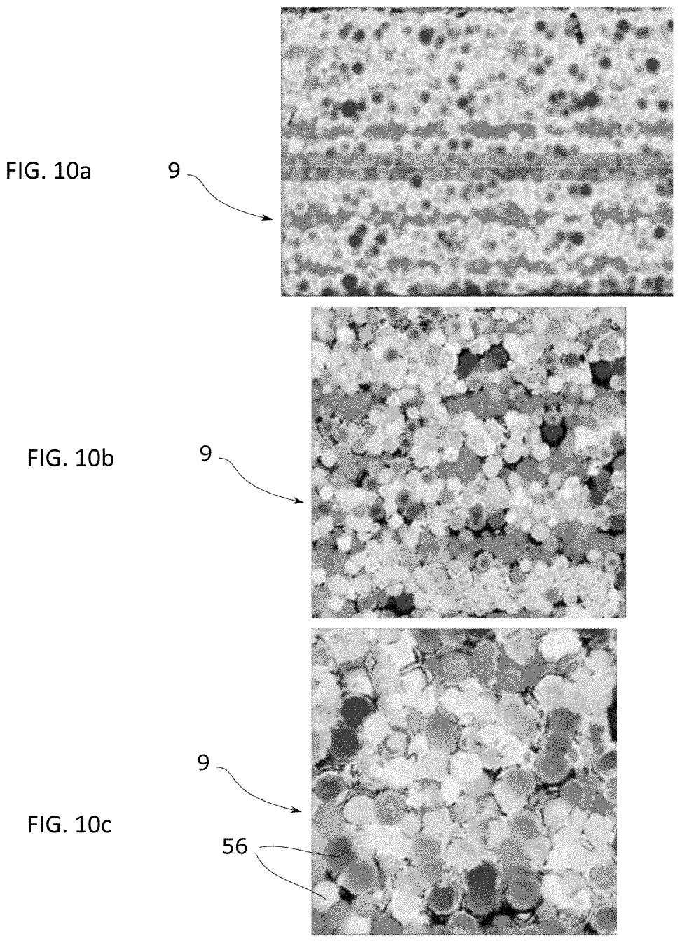

FIGS. 10a-10c show, in partial images, two-dimensional height profiles of a microstructure on the inner wall or side wall 50 of an opening. The various color values, shown here only as grayscale values, correspond to the height coordinate. The height profiles here show sections of the side wall 50 of a sample of different sizes. The measurement field sizes and the average roughness values ascertained on the basis of the sections are listed in the following table:

| Partial image | FIG. 10a | FIG. 10b | FIG. 10c |
|---|---|---|---|
| Size of | 521 μm × 831 μm | 336 μm × 336 μm | 167 μm × 167 μm |
| measurement | | | |
| field | | | |
| Average | 0.41 μm | 0.32 μm | 0.17 μm |
| roughness | | | |
| value Rₐ | | | |

FIG. 10a also shows, in the image center, a measurement distance running from left to right. The measurement distance consequently has a length of 521 μm, that is to say approximately 500 μm. As the table shows, the average roughness value with a measurement distance of 521 μm is, with 0.41 μm, less than 0.5 μm. According to a further embodiment, which is supported by the measurement according to FIG. 10b, the average roughness value Rₐ of the microstructuring 9 of the side wall 50 can be less than 0.4 μm with a measurement distance of 350 μm. According to a still further embodiment, which is supported by the measurement according to FIG. 10c, the average roughness value Rₐ of the microstructuring 9 of the side wall 50 of the opening 5 can be less than 0.25 μm with a measurement distance of 170 μm. The measurement distances in these embodiments can also be lengthened or shortened by 10%, that is to say can have lengths of 350 μm±35 μm, or 170 μm±17 μm.

In particular when viewing FIG. 10c, it becomes clear that the microstructuring 9 is composed primarily of round faces with a relatively monotonic grayscale value, thus also minor height variation. These round faces are the deeper parts of the dome-shaped depressions 56. Accordingly, the depressions 56 have a relatively flat and large bottom region. This can also be a reason why the microstructuring influences the input or output coupling of light only to a minor extent.

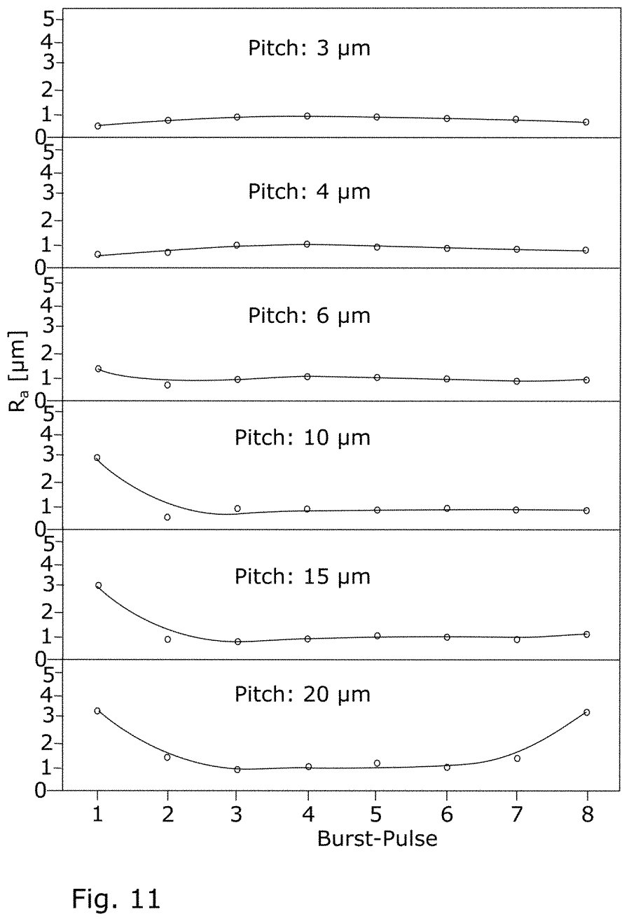

The possibility of influencing the average roughness value of the microstructuring 9 also becomes clear especially from FIG. 11.

FIG. 11 shows measurement values of the average roughness value on the side wall 50, which were produced by the above-described combination of introducing filament-type defects using an ultrashort pulse laser and subsequent etching of the defects. The measurement values are plotted as a function of the number of laser pulses within one burst for various distances between the points of incidence of the laser pulses. The number of laser pulses varies from an individual pulse to 8 pulses in burst operation of the ultrashort pulse laser. To remove the inner parts 54, a slow etching process with a duration of 48 hours was selected. As can be seen from the diagrams, particularly small distances are expedient for achieving small average roughness values. Specifically, distances of up to 4 μm are expedient. As is shown in the top two diagrams (“pitch: 3 μm” and “pitch: 4 μm”), small average roughness values are achieved in the case of these small distances with few pulses and very many pulses in a burst, even though the dependence in the case of small spatial distances between the points of incidence is not very strong. A greater roughness also manifests with a reduced etching duration (not shown in the figure). The experiments were performed with the following parameters for the etching:

A solution with 6 mol/L KOH at 100° C. was used. The removal at the side faces was 34 μm with an etching duration of 16 hours, 63 μm at 30 hours, and 97 μm at 48 hours.

Generally, the following tendencies can be read therefrom: a large pitch results in a rougher surface, and longer etching times result in smoother side faces.

The etching time on the free structure surface is one of the influencing factors for the roughness of the surface. The earlier the inner part 56 is removed, the smoother the structure can become (small pitch). The smaller the defect structure that has been introduced is, the smoother is the structure (small burst number, or low energy in the individual laser pulses due to a high pulse number). Surprisingly, the pulse length also has an influence on the roughness of the side wall. In a further experiment, the best parameters with respect to a low roughness were compared for pulses of 10 ps duration and 1 ps duration. The following results were obtained:

Best parameters at 10 ps: 1 burst/3 μm pitch and Ra=0.42 μm-0.50 μm; and

Best parameters at 1 ps: 1 burst/3 μm-10 μm pitch and Ra=0.38 μm-0.52 μm.

Etching was performed in each case with a solution of 6 mol/L KOH at 100° C., wherein 10 μm of glass were removed. Generally, it could be seen that, at very short pulse durations, the dependence on the pitch is lower. This provides a favorable parameter field that includes the above results, with a pulse duration of 0.5 ps to 2 ps (preferably 0.75 ps to 1.5 ps) and a pitch of 1 μm to 15 μm (preferably 2 μm to 12 μm).

According to a refinement of the method, at least one of the following parameters is therefore used in the method for removing the inner parts 56: the spatial distance between two points of incidence 73 of the laser beam 27 on the transparent glass plate 10 is at most 6 μm, preferably at most 4.5 μm, the etching duration is at least 12, preferably at least 20, hours, the number of pulses in a burst for introducing a filament-type defect 32 is at most 2 or at least 7, the pulse duration of the laser lies in the range from 0.5 ps to 2 ps (preferably 0.75 ps to 1.5 ps) with a spatial distance between two points of incidence 73 of the laser beam 27 on the transparent glass plate 10 of 1 μm to 15 μm (preferably 2 μm to 12 μm).

Electro-optical converter components can then be implemented with the spacer wafers 1, as are shown by way of example in FIGS. 1 and 2, or with the severed spacers 2. As mentioned above, the further processing for producing the electro-optical converter components can also take place in the wafer bond, as a result of which the severance of the spacers together takes place when severing the components from the wafer bond. Severing can be performed in this case by mechanical dicing or sawing using a separating disk. FIG. 12 in this respect shows an electro-optical converter component 3 with a frame-type spacer 2. The exemplary embodiment illustrated is one possible implementation of an embodiment of an electro-optical converter component 3 with a spacer 2, as described here, comprising a carrier 11, on which an electro-optical converter element 13 is arranged, wherein the spacer 2 is attached to the carrier 11 on the side with the electro-optical converter element 13 in a manner such that the electro-optical converter element 13 is arranged in the opening 5, and wherein a cover element 16 is arranged on the spacer 2 such that a cavity 18 that is closed laterally by the side wall 50 of the opening 5 of the spacer 2 and encloses the electro-optical converter element 13 is formed between the carrier 11 and the cover element 16. In particular, light emitted or received by the electro-optical converter element 13 can in this case traverse the cavity 18. While temperature-conductive materials are used well in many applications, glass is suitable as a material for the spacer here for example when the intention is to avoid that a high heat output is transferred to the cover element. This may be undesirable for example in the case of organic coatings of the cover or in the case of temperature-sensitive optical precision elements on the cover.

In particular according to one refinement, the spacer 2 is transparent. In this case, the converter element 13 is configured to transmit or receive light laterally between the cover element 16 and the carrier 11 through the inner side 50 of the opening 5 of the spacer 2. Possible beam paths are shown in FIG. 12 in the form of light rays 19. Where appropriate, other electromagnetic waves can be transmitted or received through the spacer 2. In particular, RF signals come to mind in this regard.

The electro-optical converter element 13 can generally be a light-emitting diode, a laser diode, or a camera chip. In the case of laser diodes, both VCSELs (VCSEL=“vertical cavity surface emitting laser”) and side-emitting laser diodes (EEL=“edge emitting laser”) can be used. In the case of EEL, coupling out the laser light through the spacer is particularly suitable. By using spacers with at least one oblique edge in connection with a deflection element, however, the laser light can be deflected such that here, too, the laser light can be coupled out vertically. The deflection element can be integrated here in the spacer, for example in the form of an optical structure or a reflective coating.

In the case of VCSELs, the laser light can for example be emitted through the cover element 16, wherein the transparent spacer 2 is utilizable to transmit scattered light for an external monitor diode.

In a housed camera chip as electro-optical converter element 13, the microstructuring of the side wall 50 having a low roughness can be advantageous if a liquid lens is placed in the cavity 18. With liquid lenses, bubbles can form on a rough wall. In addition, rough structures can influence the lens surface.

The electro-optical converter element 13 can be supplied, for example, via one or more electrical ducts 36 in the carrier 11. In the example shown, the electro-optical converter element 13 is connected to the ducts by bond wires 35. The electro-optical converter component 3 can furthermore be in the form of an SMD module. In this case, solder balls 37 can be applied onto the ducts 36. Many further types of construction exist of course. In one further possible type of construction, for example the carrier 11 itself can be an integral part of the electro-optical converter element 13, for example if the carrier 11 is a semiconductor substrate in which the electro-optical converter element 13 is formed.

In the example illustrated, only an individual electro-optical converter element 13 is enclosed in the cavity 18. However, a plurality of electro-optical converter elements 13 can be arranged in a common cavity 18. For example, an arrangement of a plurality of VCSELs can be attached to the carrier 11 within the cavity 18. Generally, different converters, such as VCSLs, EELs, LDs, can be combined with one another within the opening 5. Furthermore, one or more sensors and emitters may also be mounted together.

In one embodiment, the electro-optical converter component 3 forms a camera module, which can be used for two-dimensional image recording or for 3D capturing (3D camera imaging), as can be used for three-dimensional facial recognition.

According to yet another embodiment, the side wall 50 of the opening 5 of the frame-type spacer 2 can be coated. In the example shown in FIG. 8, the part of the side wall 50 illustrated on the right is provided with a coating 6. The coating 6 can cover the side wall 50 partially or completely. Such a coating 6 can in particular be an antireflective coating, a reflective coating, a semi-transparent coating, a color-imparting coating, or a metallic coating. It is also possible to combine a plurality of coatings to form a multi-layered coating. The coating 6 can be applied on the spacer wafer 1 even before the spacers 2 are singulated.

### LIST OF REFERENCE SIGNS

| | |
|---|---|
| Spacer wafer | 1 |
| Spacer | 2, 200, 201, 202, 203 |
| Electro-optical converter component | 3 |
| Section of 1 | 4 |
| Opening | 5 |
| Coating | 6 |
| Separating line | 7 |
| Microstructuring | 9 |
| Glass plate | 10 |
| Carrier | 11 |
| Laser processing apparatus | 12 |
| Electro-optical converter element | 13 |
| Computing device | 15 |
| Cover element | 16 |
| Positioning device | 17 |
| Cavity | 18 |
| Light ray | 19 |
| Outer wall of 2 | 20 |
| Focusing optical unit | 23 |
| Laser beam | 27 |
| Ultrashort pulse laser | 30 |
| Filament-type defect | 32 |
| Bond wire | 35 |
| Duct | 36 |
| Solder ball | 37 |
| Side wall of 5 | 50 |
| Planar section of 5 | 52, 521, 522, 523, |
| Oblique section of 5 | 520, 525 |
| Bottom surface | 526 |
| Section of 5 with structure | 524, 527 |
| Structured regions of 5 | 60, 61 |
| Closed path | 53 |
| Inner part | 54 |
| Depression | 56 |
| Point of incidence of the laser beam 27 | 73 |
| Side faces of 10 | 102, 103 |
| Channel | 105 |

What is claimed is:

1. A spacer wafer for producing frame-type spacers, comprising:
a transparent glass plate having a multiplicity of openings separated from one another and distributed in a grid so that the frame-type spacer is obtainable by severing sections of the transparent glass plate along separating lines between the multiplicity of openings,
wherein the multiplicity of openings comprise side walls with microstructuring having an average roughness value (Rₐ) of less than 0.5 μm at a measurement distance of 500 μm.

2. The spacer wafer of claim 1, wherein the side walls each have at least one planar section.

3. The spacer wafer of claim 1, wherein the side walls each have at least one oblique edge face, wherein the oblique edge face encloses an angle α≠90° with a lower side of the transparent glass plate.

4. The spacer wafer of claim 3, wherein the at least one oblique edge face has, in at least one partial region, a coating or optical structure.

5. The spacer wafer of claim 1, wherein the side walls each have at least one section in which the average roughness value (Rₐ) that is less than 50 nm at the measurement distance of 500 μm.

6. The spacer wafer of claim 1, wherein the side walls each have at least one section in which the average roughness value (Rₐ) that is less than 10 nm at the measurement distance of 50 μm.

7. The spacer wafer of claim 1, wherein the microstructuring has a multiplicity of dome-shaped depressions.

8. The spacer wafer of claim 1, further comprising a feature selected from a group consisting of: the average roughness value (Rₐ) of at least 50 nm at the measurement distance of 500 μm; the average roughness value (Rₐ) of less than 0.4 μm with the measurement distance of 350 μm; the average roughness value (Rₐ) of less than 0.25 μm with the measurement distance of 170 μm; the microstructuring being irregular; the microstructuring being such that a regular strict grid is missing; the side walls have four planar sections; the side walls have two planar sections that lie opposite each other; the side walls have three planar sections and one section with an oblique edge; a ratio of an area proportion of the microstructuring having a convexly curved surface to an area proportion having a concavely curved surface of at most 0.25; a coating on the side walls; and any combinations thereof.

9. The spacer wafer of claim 1, further comprising a feature selected from a group consisting of: a thickness of the transparent glass plate in a range from 100 μm to 3.5 mm; a thickness of the transparent glass plate in a range from 200 μm to 3.0 mm; a thickness variation of the transparent glass plate of less than 5 μm; a thickness variation of the transparent glass plate of less than 2 μm; a thickness variation of the transparent glass plate of less than 1 μm; and any combinations thereof.

10. A frame-type spacer, comprising
a transparent glass element having an opening and a frame surrounding the opening, the opening having side walls comprising microstructuring, wherein the microstructuring has an average roughness value (Rₐ) of less than 0.5 μm at a measurement distance of 500 μm.

11. The frame-type spacer of claim 10, wherein the side walls each have at least one planar section.

12. The frame-type spacer of claim 10, wherein the side walls each have at least one oblique edge face, wherein the oblique edge face encloses an angle α·90° with a lower side of the transparent glass element.

13. The frame-type spacer of claim 12, wherein the at least one oblique edge face has, in at least one partial region, a coating or optical structure.

14. The frame-type spacer of claim 10, wherein the side walls each have at least one section in which the average roughness value (Rₐ) that is less than 50 nm at the measurement distance of 500 μm.

15. The frame-type spacer of claim 10, wherein the side walls each have at least one section in which the average roughness value (Rₐ) that is less than 10 nm at the measurement distance of 50 μm.

16. The frame-type spacer of claim 10, wherein the microstructuring has a multiplicity of dome-shaped depressions.

17. The frame-type spacer of claim 10, further comprising a feature selected from a group consisting of: the average roughness value (Rₐ) of at least 50 nm at the measurement distance of 500 μm; the average roughness value (Rₐ) of less than 0.4 μm with the measurement distance of 350 μm; the average roughness value (Rₐ) of less than 0.25 μm with the measurement distance of 170 μm; the microstructuring being irregular; the microstructuring being such that a regular strict grid is missing; the side walls have four planar sections; the side walls have two planar sections that lie opposite each other; the side walls have three planar sections and one section with an oblique edge; a ratio of an area proportion of the microstructuring having a convexly curved surface to an area proportion having a concavely curved surface of at most 0.25; a coating on the side walls; a thickness of the transparent glass element in a range from 100 μm to 3.5 mm; a thickness of the transparent glass element in a range from 200 μm to 3.0 mm; a thickness variation of the transparent glass element of less than 5 μm; a thickness variation of the transparent glass element of less than 2 μm; a thickness variation of the transparent glass element of less than 1 μm; and any combinations thereof.

18. A method for producing a spacer wafer, comprising:
aiming a laser beam of an ultrashort pulse laser at a side face of a transparent glass plate;
concentrating the laser beam with a focusing optical unit to an elongate focus at a point of incidence in the transparent glass plate;
sending the laser beam in at least two successive laser pulses to produce a filament-type defect in the transparent glass plate, the filament-type defect having a longitudinal direction that runs transversely to the side face;
guiding the point of incidence along a closed path in the transparent glass plate and repeating the aiming, concentrating, and sending to introduce a multiplicity of the filament-type defects next to one another on the closed path;
exposing the transparent glass plate to an etching medium so that the multiplicity of the filament-type defects are widened until glass between the multiplicity of the filament-type defects has been removed to form an opening with side walls having microstructuring with an average roughness value (Rₐ) of less than 0.5 μm at a minimum distance of 500 μm.

19. The method of claim 18, further comprising a feature selected from a group consisting of: the transparent glass plate having glass with a removal rate of less than 5 μm per hour in the etching medium; an etching duration of at least 12 hours; a spatial distance between the multiplicity of the filament-type defects is at most 6 μm; a spatial distance between the multiplicity of the filament-type defects is at most 4.5 μm; the at least two successive laser pulses comprising at least 7 pulses; a pulse duration in a range from 0.5 ps to 2 ps; a spatial distance between two of the multiplicity of the filament-type defects of 1 μm to 15 μm; and any combinations thereof.

20. The method of claim 18, further comprising, subsequent to exposing the transparent glass plate to the etching medium, laser polishing at least one partial region of the opening.
